(19) United States
(12) Patent Application Publication
(10) Pub. No.: US 2012/0279541 A1
(43) Pub. Date: Nov. 8, 2012

(54) THERMOELECTRIC MODULE

(75) Inventors: Dong Hyeok CHOI, Gyeonggi-do (KR); Yong Suk KIM, Gyeonggi-do (KR); Sung Ho LEE, Gyeonggi-do (KR)

(73) Assignee: SAMSUNG ELECTRO-MECHANICS CO., LTD.

(21) Appl. No.: 13/412,091

(22) Filed: Mar. 5, 2012

(30) Foreign Application Priority Data
May 2, 2011 (KR) 10-2011-0041399

(51) Int. Cl. H01L 35/28

(52) U.S. Cl. 136/200

(57) ABSTRACT

Disclosed herein is a thermoelectric module using a thermoelectric element capable of showing a spin Seebeck effect. The present invention provides a new thermoelectric module including: a thermoelectric element; a first outer electrode that is connected to one side of the thermoelectric element and is applied with positive voltage; a second outer electrode that is connected to the other side of the thermoelectric element and is applied with negative voltage; an upper inner electrode layer that is embedded in an upper portion of the thermoelectric element and is mutually connected to the first outer electrode; and a lower inner electrode layer that is embedded in a lower portion of the thermoelectric element and is mutually connected to the second outer electrode.

### CROSS REFERENCE(S) TO RELATED APPLICATIONS

This application claims the benefit under 35 U.S.C. Section 119 of Korean Patent Application Serial No. 10-2011-0041399, entitled “Thermoelectric Module” filed on May 2, 2011, which is hereby incorporated by reference in its entirety into this application.

### BACKGROUND OF THE INVENTION

1. Technical Field

The present invention relates to a thermoelectric module, and more particularly, to a thermoelectric module using a spin Seebeck effect.

2. Description of the Related Art

A thermoelectric module is largely used for two applications, that is, power generation using a Seebeck effect and cooling using a Peltier effect.

The Seebeck effect is a phenomenon that generates electromotive force when a difference in temperature is generated at both ends of a thermoelectric element. The Seebeck effect is used for waste heat generation, a power supply for small electronic devices (for example, a watch) using body temperature, a power supply for a space probe using radioactive half reduction heat, or the like.

On the other hand, when current flows to both ends of the thermoelectric element, heat moves with the movement of charges. The phenomenon in which one end of the thermoelectric element is cooled and the other end of the thermoelectric element is heated is the Peltier effect. A cooling device using only electrons without a mechanical operation may be manufactured by using the Peltier effect.

The thermoelectric module according to the related art is configured to largely include an insulating substrate, metal electrodes, p-type semiconductor devices, and n-type semiconductor devices and has a series type single module form in which the p-type semiconductor devices through which holes move and the n-type semiconductor devices through which electrons move are electrically connected to each other in series via the metal electrodes.

Describing an operation state implemented by the thermoelectric module according to the above-mentioned type, when the n-type thermoelectric semiconductor devices and the p-type thermoelectric semiconductor devices are electrically connected to each other in series via the metal electrodes and apply DC current (D. C.) via lead wires, heat absorption is generated at metal/semiconductor contacts and charged with negative by moving electrons absorbing heat energy from surroundings into a thermoelectric semiconductor and heat radiation is generated at the metal/semiconductor contacts and charged with positive by discharging heat energy from electrons. However, even though the thermoelectric module is optimized by using a thermoelectric material, the heat absorption and/or heat radiation amount per supply power of a thermocouple in which the n-type thermoelectric semiconductor and the p-type thermoelectric semiconductor are configured as a pair is very insignificant. For this reason, when the thermoelectric module 100 according to the related art is actually used for a cooling device, or the like, the heat absorption and/or heat radiation amount is quantitatively increased by connecting a plurality of thermocouples and thus, the efficiency thereof is degraded in comparison to the manufacturing cost.

In addition, since the thermoelectric module 100 is configured in a series type single module form in which the n and p-type semiconductor devices formed in plural pairs are electrically connected to each other in series via the metal electrodes, there is a fatal problem in that the overall composite module may not be operated if any one of the single modules is defective.

Further, as the thermoelectric material used for the thermoelectric element, Bi—Te based, Fe—Si based, Co—Sb based, Si—Ge based materials, or the like, are actually used. Since the practical use range of these materials is very limited, a large problem is not caused so far. However, if these materials are used when the temperature of recovered waste heat is at a high temperature reaching 300° C. to 600° C., there are problems in that reliability of an operation is degraded due to the occurrence of surface oxidation, or the like, and material costs are very expensive.

Further, since the thermoelectric module has a configuration in which bottom surfaces of an n-type thermoelectric element and a p-type thermoelectric element adjacent to each other are connected to each by a first metal electrode and top surfaces of the p-type thermoelectric element and the n-type thermoelectric element adjacent to each other are connected to each other by a second metal electrode in the state in which the n-type thermoelectric element and the p-type thermoelectric element are alternately arranged in sequence, the thermoelectric module has many adhesive layers such as soldering, a bonding material, or the like. In this case, there are problems in that electric resistance is increased and a process of manufacturing the thermoelectric module is complicated to increase manufacturing costs.

Recently, researchers of Eiji Saitoh at Keio University of Japan found that electrons are aligned according to their own spin at the time of heating one side of a magnetized nickel-iron rod (Uchida, K., et al, Observation of The Spin Seebeck Effect, Nature 455, (2008)). The foregoing so-called spin Seebeck effect generates magnetic currents rather than generating electric currents. The term spin Seebeck effect is sourced from a Seebeck effect that is a thermoelectric phenomenon found by Thomas Johann Seebeck in the 1980s. The Seebeck effect means generating voltage by moving electrons absorbing heat to a cold area when one side of a conductive rod is heated. The spin Seebeck effect is similar to the Seebeck effect, but affects the electron spin unlike the Seebeck effect and collects electrons having an up spin to a hot area and collects electrons having a down spin to a cold area when a magnetized metal such as a nickel-iron rod is heated. Therefore, since the foregoing spin separating rod may be considered as having two electrodes, it is possible to form spin voltage or magnetic current that is not easily generated.

### SUMMARY OF THE INVENTION

An object of the present invention is to provide a thermoelectric module using a spin Seebeck effect. A technical problem of the present invention is to provide a thermoelectric module configured to include a thermoelectric element made of a thermoelectric material showing a spin Seebeck effect and inner electrode layers embedded in an upper portion and a lower portion of the thermoelectric element and outer electrodes connected to the inner electrode layers and applied with voltage.

According to an exemplary embodiment of the present invention, there is provided a thermoelectric module, including: a thermoelectric element; a first outer electrode that is connected to one side of the thermoelectric element and is applied with positive voltage; a second outer electrode that is connected to the other side of the thermoelectric element and is applied with negative voltage; an upper inner electrode layer that is embedded in an upper portion of the thermoelectric element and is mutually connected to the first outer electrode; and a lower inner electrode layer that is embedded in a lower portion of the thermoelectric element and is mutually connected to the second outer electrode.

The thermoelectric element may be made of soft ferrite and may include at least any one of spinel ferrite having a chemical formula of MeOFe₂O₃ (herein, Me may include Mn, Fe, Co, Ni, Cu, Zn, Mg, and Cd), garnet ferrite having a chemical formula of Re₃Fe₅O₁₂ (herein, Re may include all the rare earth-based elements, and all the magnetic materials having soft magnetism among metal oxides.

The first outer electrode may be configured of a first pole and a second pole and the upper inner electrode layer may be formed in a form having both ends, wherein the first pole of the first outer electrode may be connected to one end of the upper inner electrode layer and the second pole of the first outer electrode may be connected to the other end of the upper inner electrode layer.

The second outer electrode may be configured of a first pole and a second pole and the lower inner electrode layer may be formed in a form having both ends, wherein the first pole of the second outer electrode may be connected to one end of the lower inner electrode layer and the second pole of the second outer electrode may be connected to the other end of the lower inner electrode layer.

The first pole and the second pole may be spaced apart from each other so as not to contact each other.

A distance between the upper inner electrode layer and the lower inner electrode layer may be set in a length range in a z-axis direction of the thermoelectric element and the upper inner electrode layer and the lower inner electrode layer may be spaced apart from each other so that they do not contact each other.

The inner electrode layer may be formed in plural layers.

### BRIEF DESCRIPTION OF THE DRAWINGS

FIG. 1 is a perspective view showing an external appearance of a thermoelectric module according to an exemplary embodiment of the present invention;

FIG. 2 is a perspective view showing an inside of the thermoelectric module according to the exemplary embodiment of the present invention;

FIG. 3 is a longitudinal cross-sectional view of the thermoelectric module of FIG. 1;

FIG. 4 is a transversal cross-sectional view of the thermoelectric module of FIG. 1; and

FIG. 5 is a longitudinal cross-sectional view of the thermoelectric module according to another exemplary embodiment of the present invention.

### DESCRIPTION OF THE PREFERRED EMBODIMENTS

Hereinafter, exemplary embodiments of the present invention will be described in detail with reference to the accompanying drawings. However, the exemplary embodiments of the present invention may be modified in various forms and the scope of the present invention is not limited to the exemplary embodiments described below. Exemplary embodiments of the present invention are provided so that those skilled in the art may more completely understand the present invention. Accordingly, shapes and sizes of elements in the drawings may be exaggerated for clear description and like reference numerals refer to like elements throughout the drawings.

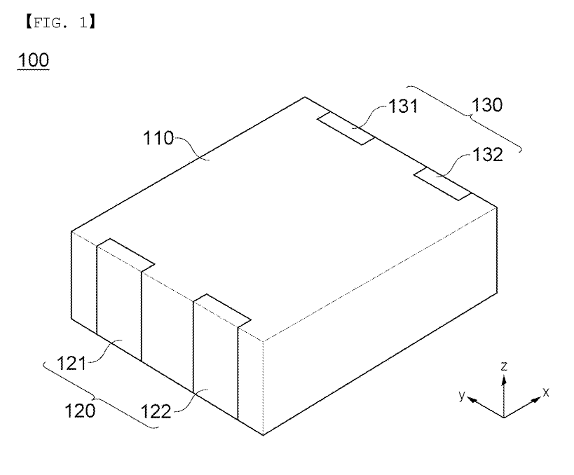

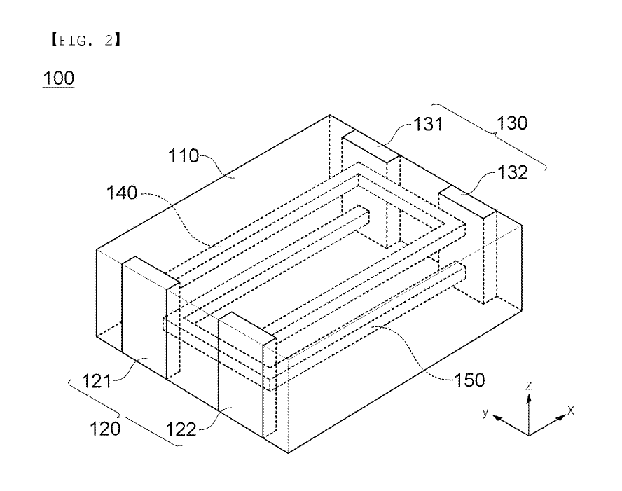

FIG. 1 is a perspective view showing an external appearance of a thermoelectric module 100 according to an exemplary embodiment of the present invention and FIG. 2 is a perspective view showing an inside of the thermoelectric module 100 according to the exemplary embodiment of the present invention.

As shown in FIGS. 1 and 2, the thermoelectric module 100 according to the exemplary embodiment of the present invention may be configured to include a thermoelectric element 110 made of a thermoelectric material showing a spin Seebeck effect, a first outer electrode 120 that is connected to one side of the thermoelectric element 110 and is applied with positive voltage, a second outer electrode 130 that is connected to the other side of the thermoelectric element 110 and is applied with negative voltage, an upper inner electrode layer 140 that is embedded in an upper portion of the thermoelectric element 110 and is mutually connected to the first outer electrode 120, and a lower inner electrode layer 150 that is embedded in a lower portion of the thermoelectric element 110 and is mutually connected to the second outer electrode 130.

In this configuration, the thermoelectric material showing the spin Seebeck effect means a soft ferrite material, not a general n-type and p-type thermoelectric material used in an existing thermoelectric module having semiconductor characteristics. The soft ferrite is an insulator without electrically moving electrons and means a magnetic material that may easily change the spin arrangement by an external magnetic field while having magnetic characteristics generated due to an arrangement of an electron spin. An example of a representative soft ferrite may include spinel ferrite having a chemical formula of MeOFe₂O₃ (where Me may include Mn, Fe, Co, Ni, Cu, Zn, Mg, and Cd) such as NiZnCu-ferrite, garnet ferrite having a chemical formula of Re₃Fe₅O₁₂ (where Re may include all the rare earth-based elements), and all the magnetic materials having soft magnetism among metal oxides.

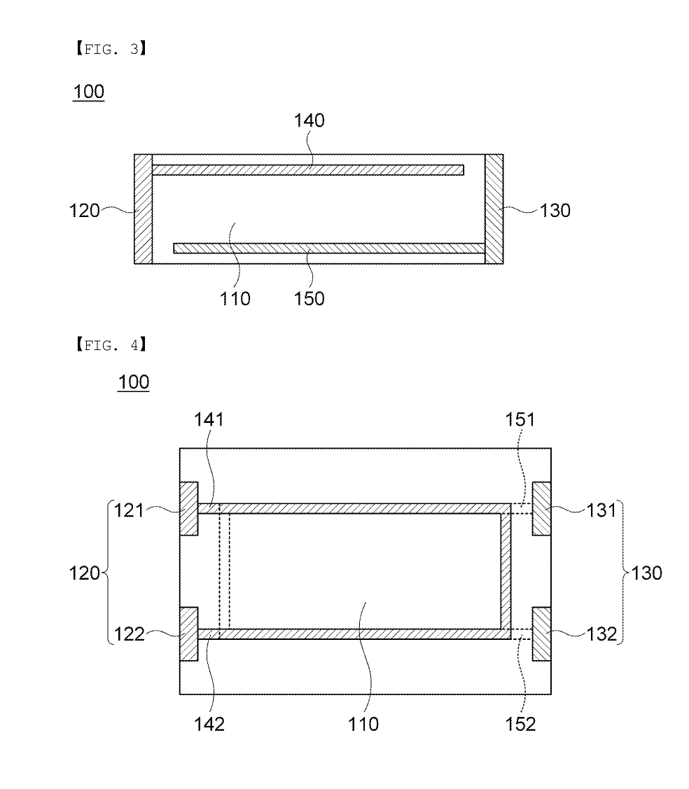

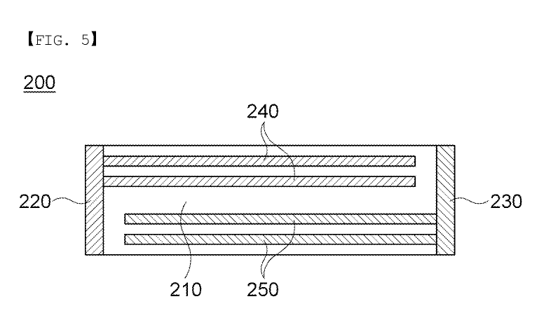

FIG. 3 is a longitudinal cross-sectional view of the thermoelectric module of FIG. 1 and FIG. 4 is a transversal cross-sectional view of the thermoelectric module of FIG. 1. Referring to FIGS. 3 and 4, the first and second outer electrodes 120 and 130 may each be configured of first poles 121 and 131 and second poles 122 and 132 and the upper and lower inner electrode layers 140 and 150 may be formed in a form having both ends. Therefore, describing the first outer electrode 120 and the upper inner electrode layer 140 as an example, the first pole 121 of the first outer electrode 120 may be connected to one end 141 of the upper inner electrode layer 140 and the second pole 122 of the first outer electrode 120 may be connected to the other end 142 of the upper inner electrode layer 140, such that the first outer electrode 120 and the upper inner electrode layer 140 may be connected to each other. Similarly, the first pole 131 of the second outer electrode 130 may be connected to one end 151 of the lower inner electrode layer 150 and the second pole 132 of the second outer electrode 130 may be connected to the other end 152 of the lower inner electrode layer 150, such that the second outer electrode 130 and the lower inner electrode layer 150 may be connected to each other.

However, in order to flow current to the upper or lower inner electrode layers 140 and 150 through the first poles 121 and 131 and the second poles 122 and 132, the first poles 121 and 131 and the second poles 122 and 132 may be configured in a form spaced apart from each other so that they do not contact each other.

In the thermoelectric module 100 according to the exemplary embodiment of the present invention, the upper and lower inner electrode layers 140 and 150 each applies voltage to the upper surface and the lower surface of the thermoelectric element 110 in different directions to control the spin direction of the upper surface and the lower surface within the thermoelectric element 110, such that the spin direction of electrons within the thermoelectric element 110 are aligned differently by the foregoing spin Seebeck effect when positive voltage is applied to the upper inner electrode layer 140 through the foregoing connection structure and negative voltage is applied to the lower inner electrode layer 150, thereby generating a temperature difference by ΔT at the lower surface of the thermoelectric element 110 rather than at the upper surface thereof. As a result, the upper surface of the thermoelectric element 110 may absorb heat from the surroundings and the lower surface of the thermoelectric element 110 may discharge heat, such that the thermoelectric element 110 may be applied to an element or a system necessary for cooling and warming.

In this configuration, a material forming the inner electrode layers 140 and 150 and the first and second outer electrodes 120 and 130 may include at least one of aluminum (Al), copper (Cu), tungsten (W), titanium (Ti), silver (Ag), gold (Au), platinum (Pt), nickel (NI), carbon (C), molybdenum (Mo), tantalum (Ta), iridium (Ir), ruthenium (Ru), zinc (Zn), tin (Sn), and indium (In).

Meanwhile, a distance between the upper inner electrode layer 140 and the lower inner electrode layer 150 may be set in a length range in a z-axis direction of the thermoelectric element 110. However, the upper inner electrode layer 140 and the lower inner electrode layer 150 may be configured in a form spaced apart from each other so that they do not contact each other.

That is, the distance between the upper inner electrode layer 140 and the lower inner electrode layer 150 may be freely set within the length range in a y-axis direction of the thermoelectric element 110 through an experiment so as to most actively move heat according to the spin Seebeck effect, but may be set so that the upper inner electrode layer 140 does not contact the lower inner electrode layer 150, in order to prevent the short between the upper inner electrode layer 140 and the lower inner electrode layer 150.

In addition, a length in an x-axis direction of the upper or lower inner electrode layers 140 and 150 may be freely set within the range capable of implementing the spin Seebeck effect, but may be set as long as possible so as to improve the thermoelectric performance.

The configuration of the thermoelectric module 100 according to the exemplary embodiment of the present invention is a module configuration that may be designed corresponding to an operational principle of the spin Seebeck effect, which is a module configuration that cannot be implemented in the thermoelectric module including the existing n-type and p-type thermoelectric elements. The thermoelectric module 100 according to the exemplary embodiment of the present invention has a form in which the inner electrode layer is embedded in the thermoelectric element 110 so as to move heat, such that it is advantageous in implementing the thermoelectric module as a thin type unlike the existing n-type and p-type thermoelectric modules.

In addition, the configuration of the thermoelectric module 100 according to the exemplary embodiment of the present invention is similar to a configuration of a multi-layer ceramic capacitor (MLCC), such that the thermoelectric module 100 according to the exemplary embodiment of the present invention may be manufactured by the existing MLCC process. Further, the material of the thermoelectric element 110 is more inexpensive than the n-type and p-type thermoelectric semiconductor devices, thereby saving manufacturing costs.

Meanwhile, when negative voltage is applied to the first outer electrode 120 and positive voltage is applied to the second outer electrode 130, heat may move from the lower surface of the thermoelectric element 110 to the upper surface thereof.

FIG. 5 is a longitudinal cross-sectional view of a thermoelectric module 200 according to another exemplary embodiment of the present invention. Referring to FIG. 5, the thermoelectric module 200 according to another exemplary embodiment of the present invention may be configured to include a thermoelectric element 210 made of a thermoelectric material showing a spin Seebeck effect, a first outer electrode 220 that is connected to one side of the thermoelectric element 210 and is applied with positive voltage, a second outer electrode 230 that is connected to the other side of the thermoelectric element 110 and is applied with negative voltage, an upper inner electrode layer 240 that is embedded in an upper portion of the thermoelectric element 210 and is mutually connected to the first outer electrode 220, and a lower inner electrode layer 250 that is embedded in a lower portion of the thermoelectric element 210 and is mutually connected to the second outer electrode 230, similar to the foregoing thermoelectric module 100 according to the exemplary embodiment of the present invention. However, the upper or lower inner electrode layers 240 and 250 may be formed in plural layers.

In this configuration, the thermoelectric element 210 may include all the magnetic materials having soft magnetism among spinel ferrite having a chemical formula of MeOFe₂O₃ (herein, Me may include Mn, Fe, Co, Ni, Cu, Zn, Mg, and Cd), garnet ferrite having a chemical formula of Re₃Fe₅O₁₂ (herein, Re may include all the rare earth-based elements, and metal oxide. Further, the first and second outer electrodes 230 may each be configured of the first pole and the second pole and the upper and lower inner electrode layers 250 may be configured in a form having both ends. Therefore, each of the plurality of upper inner electrode layers 240 may mutually be connected to the first outer electrode 220 and similarly, each of the plurality of lower inner electrode layers 250 may mutually be connected to the second outer electrode 230.

As described above, the upper or lower inner electrode layers 240 and 250 are configured in plural to more effectively control the spin direction in which electrons in the thermoelectric material configuring the thermoelectric element are aligned, thereby expecting more effective thermoelectric performance. However, the number of inner electrode layers may be complementarily controlled considering a size specification of the required thermoelectric module.

As set forth above, the exemplary embodiment of the present invention can simplify the manufacturing process of the thermoelectric module by being configured in the form in which the inner electrode layers are embedded in the thermoelectric element, thereby saving the manufacturing costs.

In addition, the exemplary embodiment of the present invention can implement the thermoelectric module through the outer electrodes and the inner electrode layers by being configured in the form in which the inner electrode layers connected to the outer electrodes are integral with the thermoelectric element, thereby facilitating the thinness of the thermoelectric module.

While the present invention has been shown and described in connection with the exemplary embodiments, it will be apparent to those skilled in the art that modifications and variations can be made without departing from the spirit and scope of the invention as defined by the appended claims.

What is claimed is:

1. A thermoelectric module, comprising:
a thermoelectric element;
a first outer electrode that is connected to one side of the thermoelectric element and is applied with positive voltage;
a second outer electrode that is connected to the other side of the thermoelectric element and is applied with negative voltage;
an upper inner electrode layer that is embedded in an upper portion of the thermoelectric element and is mutually connected to the first outer electrode; and
a lower inner electrode layer that is embedded in a lower portion of the thermoelectric element and is mutually connected to the second outer electrode.

2. The thermoelectric module according to claim 1, wherein the thermoelectric element is made of soft ferrite and includes at least any one of spinel ferrite having a chemical formula of MeOFe₂O₃ (where Me includes Mn, Fe, Co, Ni, Cu, Zn, Mg, and Cd), garnet ferrite having a chemical formula of Re₃Fe₅O₁₂ (where Re includes all the rare earth-based elements), and all the magnetic materials having soft magnetism among metal oxides.

3. The thermoelectric module according to claim 1, wherein the first outer electrode is configured of a first pole and a second pole and the upper inner electrode layer is formed in a form having both ends, the first pole of the first outer electrode being connected to one end of the upper inner electrode layer and the second pole of the first outer electrode being connected to the other end of the upper inner electrode layer.

4. The thermoelectric module according to claim 1, wherein the second outer electrode is configured of a first pole and a second pole, and the lower inner electrode layer is formed in a form having both ends, the first pole of the second outer electrode being connected to one end of the lower inner electrode layer and the second pole of the second outer electrode being connected to the other end of the lower inner electrode layer.

5. The thermoelectric module according to claim 3 or 4, wherein the first pole and the second pole are spaced apart from each other so as not to contact each other.

6. The thermoelectric module according to claim 1, wherein a distance between the upper inner electrode layer and the lower inner electrode layer is set in a length range in a z-axis direction of the thermoelectric element and the upper inner electrode layer and the lower inner electrode layer are spaced apart from each other so that they do not contact each other.

7. The thermoelectric module according to claim 1, wherein the inner electrode layer is formed in plural layers.
